(19) United States
(12) Patent Application Publication
(10) Pub. No.: US 2003/0064595 A1
(43) Pub. Date: Apr. 3, 2003

(54) Chemical mechanical polishing defect reduction system and method

(76) Inventor: Michael Shu-Huan Wang, Plano, TX (US)

Correspondence Address: TEXAS INSTRUMENTS INCORPORATED, P O BOX 655474, M/S 3999, DALLAS, TX, 75265

(21) Appl. No.: 10/246,956

(22) Filed: Sep. 19, 2002

Related U.S. Application Data
(60) Provisional application No. 60/326,001, filed on Sep. 28, 2001.

(51) Int. Cl. C23F 1/00; C03C 15/00; B44C 1/22; H01L 21/302

(52) U.S. Cl. 438/692; 216/89

(57) ABSTRACT

According to one embodiment of the invention, a method for removing particles from a conditioner disk used in a chemical mechanical polishing system includes submersing the conditioner disk in a fluid medium and introducing a vibrational energy to the fluid medium. The fluid medium may be deionized water and the vibrational energy may be ultrasonically introduced.

### TECHNICAL FIELD OF THE INVENTION

The present invention relates generally to semiconductor wafer processing and, more particularly, to a chemical mechanical polishing (“CMP”) defect reduction system and method.

### BACKGROUND OF THE INVENTION

Chemical mechanical polishing (“CMP”) is a semiconductor wafer planarizing and/or polishing procedure widely used in the fabrication of semiconductor wafers. As the name implies, there are two components to the process: chemical and mechanical polishing. Chemical polishing involves the introduction of chemicals that dissolve imperfections and impurities present upon the wafer. Mechanical polishing involves rotating the wafer upon an abrasive pad in order to planarize the wafer.

Generally, the wafers are mounted upside down on a wafer carrier and rotated above a polishing pad sitting on a platen. The platen is also rotated. Typically, a slurry containing both chemicals and abrasives is introduced upon the pad. The more defect-free the pad is, the less defects that are imparted to the wafer. Therefore, it is desirable to keep the pad as defect-free as possible.

### SUMMARY OF THE INVENTION

According to one embodiment of the invention, a method for removing particles from a conditioner disk used in a chemical mechanical polishing system includes submersing the conditioner disk in a fluid medium and introducing a vibrational energy to the fluid medium. The fluid medium may be deionized water and the vibrational energy may be ultrasonically introduced.

Embodiments of the invention provide a number of technical advantages. Embodiments of the invention may include all, some, or none of these advantages. Reducing defects in semiconductor wafers during a chemical mechanical polishing (“CMP”) process greatly improves yield. In one embodiment, ultrasonic cleaning of a conditioner disk is a more effective method of removing embedded debris and conglomerated slurry on the conditioner disk than spraying deionized water. A conditioner disk may be cleaned uniformly across its entire surface, and does not have to be removed to be cleaned. The cleaning may be performed when the disk is in a conditioner clean cup, which saves time.

Other technical advantages are readily apparent to one skilled in the art from the following figures, descriptions, and claims.

### BRIEF DESCRIPTION OF THE DRAWINGS

For a more complete understanding of the present invention and its advantages, reference is now made to the following descriptions, taken in conjunction with the accompanying drawings, in which:

FIG. 1 is an elevation view of a chemical mechanical polishing (“CMP”) system in accordance with one embodiment of the present invention;

FIG. 2 is a plan view of the CMP system of FIG. 1;

FIG. 3 is an elevation view of a system for cleaning a conditioning disk of the CMP system of FIG. 1; and

FIG. 4 is a flowchart illustrating a method for reducing defects in semiconductor wafers in a CMP system according to the teachings of the present invention.

### DETAILED DESCRIPTION OF EXAMPLE EMBODIMENTS OF THE INVENTION

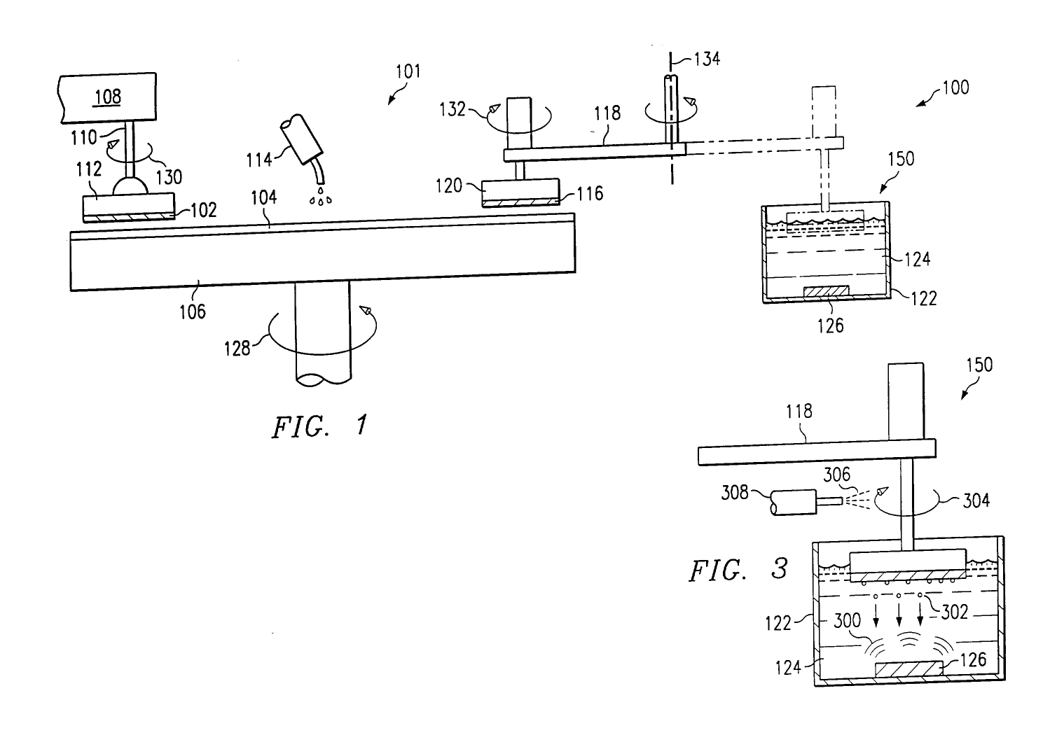

Example embodiments of the present invention and their advantages are best understood by referring now to FIGS. 1 through 4 of the drawings, in which like numerals refer to like parts.

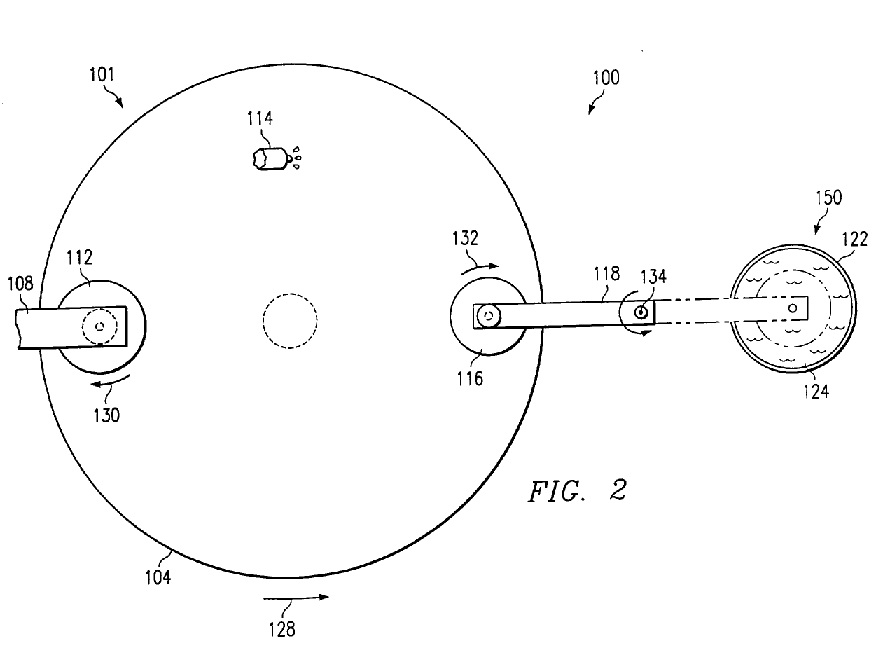

FIG. 1 is an elevation view and FIG. 2 is a plan view of a chemical mechanical polishing (“CMP”) system 100 in accordance with one embodiment of the present invention. CMP system 100 includes a polishing station 101 and a cleaning station 150. Polishing station 101 functions to polish and/or planarize one or more semiconductor wafers 102 during the processing of semiconductor wafers 102. One example of polishing station 101 is the Mirra Mesa CMP machine manufactured by Applied Materials®; however, other suitable polishing stations may be utilized within the teachings of the present invention. The type of polishing station 101, along with the size, shape, and configuration of various components illustrated may be varied significantly within the teachings of the present invention.

As illustrated, Polishing station 101 includes a polishing pad 104 coupled to a platen 106, a wafer holder 108 having a spindle 110 and a wafer carrier 112 for manipulating wafer 102, a slurry delivery system 114, a conditioner disk 116, and a conditioner disk actuating arm 118 having a conditioner disk carrier 120 for manipulating conditioner disk 116. Cleaning station 150, according to the teachings of the present invention, includes a clean cup 122, a fluid medium 124, and a frequency generator 126.

As illustrated by arrow 128, platen 106 and polishing pad 104 are configured to rotate during the CMP process. In addition, wafer carrier 112 through spindle 110 and wafer holder 108 facilitates the rotation of wafer 102, typically in a direction opposite that of platen 106 and polishing pad 104. Accordingly, when wafer 102 engages polishing pad 104, while both are rotating, wafer 102 is polished and/or planarized to provide a clean, flat surface on wafer 102.

Slurry delivery system 114 provides a liquid slurry to polishing pad 104 to enhance the polishing process. Liquid slurry may include acids and/or other chemicals that interact with wafer 102 in order to loosen, or at least partially remove, metals, oxidation, and other impurities present upon wafer 102. The liquid slurry may also include small particles of glass and/or other suitable abrasive materials that grind wafer 102 during the polishing process.

Since polishing pad 104, along with the liquid slurry, polishes wafer 102, it is important that polishing pad 104 be as defect-free as possible. Any particles or other foreign matter that adversely affects the surface of polishing pad 104 has a tendency to scratch a surface of wafer 102 during the CMP process. This is one reason why conditioner disk 116 is used in CMP system 100.

Conditioner disk 116 conditions polishing pad 104 so that polishing pad 104 may perform its polishing and/or planarizing function more effectively. As denoted by arrow 132, conditioner disk 116 is rotated via conditioner disk actuating arm 118 and conditioner disk carrier 120 before engaging polishing pad 104 during the CMP process. Typically, conditioner disk 116 is a perforated or non-perforated metal plate, circular in shape, that has microscopic diamond particles on a surface thereof for conditioning polishing pad 104. However, any suitable conditioning disk 116 may be utilized in accordance with the teachings of the present invention. Conditioner disk actuating arm 118 is rotatable about a pivot 134 to transfer conditioning disk 116 to cleaning station 150, as described more fully below.

As described above, cleaning station 150 includes clean cup 122 containing a fluid medium 124 and a frequency generator 126. According to the teachings of the present invention, frequency generator 126 introduces a vibrational energy to fluid medium 124 to remove embedded particles and other unwanted material from the surface of conditioner disk 116 when conditioner disk 116 is submersed in fluid medium 124. The details of how cleaning station 150 accomplishes this is described more fully below in conjunction with FIG. 3.

Clean cup 122 may be any suitable container used to house fluid medium 124, such as containers formed from plastic, metals, or other suitable materials. Clean cup 122 may have any suitable size and shape that may accommodate the size and shape of conditioner disk 116.

Fluid medium 124, in one embodiment, is deionized water. However, other suitable fluid media may be utilized, such as water, potassium hydroxide, and other suitable chemicals.

Frequency generator 126, as described above, functions to introduce a vibrational energy to fluid medium 124. This vibrational energy facilitates the removal of conglomerated slurry and other foreign particles that are embedded on the surface of conditioner disk 116, as described more fully below in conjunction with FIG. 3. In one embodiment, frequency generator 126 is an ultrasonic transducer; however, other suitable mechanical, electromechanical, or electrical devices may be utilized to impart vibrational energy to fluid medium 124, such as a megasonic transducer and a piezoelectric drive element. Although in the illustrated embodiment frequency generator 126 is shown to be submersed in fluid medium 124, in other embodiments, frequency generator 126 is adjacent an outer surface of clean cup 122.

FIG. 2 better illustrates the ability of conditioner disk actuating arm 118 to rotate about pivot access 134 so that conditioner disk 116 may be transferred from polishing station 101 to cleaning station 150. This movement may be easily automated such that when a polishing cycle is finished for any number of wafers 102 conditioner disk 116 may be cleaned at cleaning station 150 when other wafers 102 are moved into position for polishing and/or planarizing. This saves considerable time because conditioner disk 116 does not have to be removed from conditioner disk carrier 120 to be cleaned.

FIG. 3 is an elevation view illustrating cleaning station 150 in greater detail. As illustrated in FIG. 3, conditioner disk 116 has been transferred to cleaning station 150. Conditioner disk 116 via conditioner disk carrier 120 and conditioner disk actuating arm 118 is lowered into fluid medium 124 for cleaning. Frequency generator 126 then introduces vibrational energy, as denoted by reference numeral 300, to fluid medium 124. Vibrational energy 300 functions to remove embedded particles 302 from a surface of conditioner disk 116 to keep the conditioning surface clean. In one embodiment, conditioner disk 116 may be rotated as denoted by reference numeral 304 during the cleaning process. In addition, in other embodiments, deionized water 306 may be sprayed on by a deionized water system 308 either before or after conditioner disk 116 is submerged in fluid medium 124. Deionized water system 308 would provide an extra cleaning method for conditioner disk 116. When CMP system 100 is ready to polish and/or planarize other wafers 102 then conditioner disk actuating arm 118 and conditioner disk carrier 120 raises conditioner disk 116 out of fluid medium 124 and rotates it around pivot access 134 back to polishing station 101 so that conditioner disk 116 may perform its function in keeping polishing pad 104 defect-free, thereby avoiding scratches and other imperfections in a surface of wafer 102. Keeping polishing pad 104 as defect-free as possible improves yield, which saves considerable money.

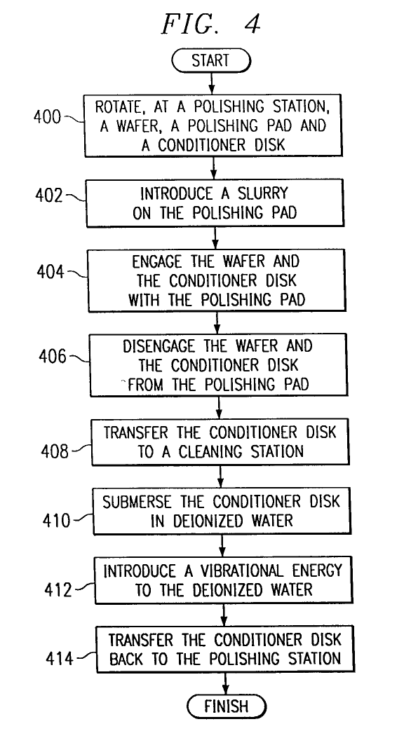

FIG. 4 is a flowchart illustrating one method for reducing scratches and defects in wafers 102 in CMP system 100 according to one embodiment of the present invention. The method begins at step 400 where wafer 102, polishing pad 104, and conditioner disk 116 are rotated at polishing station 101. A slurry from slurry delivery system 114 is introduced on polishing pad 104 at step 402, and wafer 102 and conditioner disk 116 are engaged with polishing pad 104 at step 404 to accomplish the polishing and/or planarizing of one or more wafers 102. When wafer 102 reaches a desired thickness or a desired surface smoothness, wafer 102 and conditioner disk 116 are disengaged from polishing pad 104 at step 406. Conditioner disk 116 is then transferred at step 408 to cleaning station 150 so that any embedded debris, conglomerated slurry, or other unwanted matter may be removed from conditioner disk 116. At step 410, conditioner disk 116 is submersed in fluid medium 124, such as deionized water, and vibrational energy 300 is introduced into fluid medium 124 at step 412. Vibrational energy 300 loosens particles 302 from the surface of conditioner disk 116, thereby cleaning conditioner disk 116 so that it may be ready for the next polishing and/or planarizing cycle. As an added protection for cleaning purposes, deionized water 306 may be sprayed on by deionized water delivery system 308 either before or after conditioner disk 116 is submersed in fluid medium 124. After conditioner disk 116 is cleaned, conditioner disk 116 is transferred back to polishing station 101 so that a new polishing and/or planarizing cycle may take place. This ends one method of reducing defects and scratches in wafers 102 in CMP system 100.

Although embodiments of the invention and their advantages are described in detail, a person skilled in the art could make various alterations, additions, and omissions without departing from the spirit and scope of the present invention as defined by the appended claims.

What is claimed is:

1. A chemical mechanical polishing method, comprising:
rotating, at a polishing station, a wafer, a polishing pad, and a conditioner disk;
introducing a slurry on the polishing pad;
engaging the wafer and the conditioner disk with the polishing pad;
disengaging the wafer and the conditioner disk from the polishing pad;
transferring the conditioner disk to a cleaning station;
submersing the conditioner disk in deionized water;
introducing a vibrational energy to the deionized water; and
transferring the conditioner disk back to the polishing station.

2. The method of claim 1, further comprising rotating the conditioner disk while submersed in the fluid medium.

3. The method of claim 1, wherein submersing the conditioner disk in the fluid medium comprises submersing the conditioner disk in potassium hydroxide.

4. The method of claim 1, wherein introducing the vibrational energy to the fluid medium comprises ultrasonically introducing a vibrational energy to the deionized water.

5. The method of claim 1, wherein introducing the vibrational energy to the fluid medium comprises megasonically introducing a vibrational energy to the deionized water.

6. The method of claim 1, further comprising spraying, before or after submersing the conditioner disk in the deionized water, deionized water on the conditioner disk.

7. A method for removing particles from a conditioner disk used in a chemical mechanical polishing system, comprising:
submersing the conditioner disk in a fluid medium; and
introducing a vibrational energy to the fluid medium.

8. The method of claim 7, further comprising rotating the conditioner disk while submersed in the fluid medium.

9. The method of claim 7, wherein submersing the conditioner disk in the fluid medium comprises submersing the conditioner disk in deionized water.

10. The method of claim 7, wherein submersing the conditioner disk in the fluid medium comprises submersing the conditioner disk in water.

11. The method of claim 7, wherein submersing the conditioner disk in the fluid medium comprises submersing the conditioner disk in potassium hydroxide.

12. The method of claim 7, wherein introducing the vibrational energy to the fluid medium comprises ultrasonically introducing a vibrational energy to the fluid medium.

13. The method of claim 7, wherein introducing the vibrational energy to the fluid medium comprises megasonically introducing a vibrational energy to the fluid medium.

14. The method of claim 7, wherein introducing the vibrational energy to the deionized water comprises ultrasonically introducing a vibrational energy to the deionized water.

15. The method of claim 7, further comprising spraying, before or after submersing the conditioner disk in the fluid medium, deionized water on the conditioner disk.

16. A system for removing particles from a conditioner disk used in a chemical mechanical polishing system, comprising:
a polishing station;
a cleaning station adjacent the polishing station; and
a conditioner disk actuating arm operable to transfer the conditioner disk between the polishing station and the cleaning station, the cleaning station comprising:
a container;
a fluid medium disposed in the container; and
a frequency generator submersed in the fluid medium, the frequency generator operable to introduce a vibrational energy to the fluid medium when the conditioner disk is submersed in the fluid medium.

17. The system of claim 16, wherein the conditioner disk actuating arm is operable to rotate the conditioner disk when submersed in the fluid medium.

18. The system of claim 16, wherein the fluid medium comprises a fluid medium selected from the group consisting of deionized water, water, and a potassium hydroxide.

19. The system of claim 16, wherein frequency generator is an ultrasonic transducer.

20. The system of claim 16, frequency generator is a megasonic transducer.
